(19) United States
(12) Patent Application Publication
(10) Pub. No.: US 2006/0232292 A1
(43) Pub. Date: Oct. 19, 2006

(54) Semiconductor integrated circuit and method for testing connection state between semiconductor integrated circuits

(76) Inventors: Kazutoshi Shimizume, Kanagawa (JP); Hiroaki Mizoguti, Kagoshima (JP)

Correspondence Address: William S. Frommer, Esq.;FROMMER LAWRENCE & HAUG LLP, 745 Fifth Avenue, New York, NY, 10151, US

(21) Appl. No.: 11/401,754

(22) Filed: Apr. 11, 2006

(30) Foreign Application Priority Data
Apr. 13, 2005 (JP) 2005-116209

(51) Int. Cl. G01R 31/26

(52) U.S. Cl. 324/765

(57) ABSTRACT

A semiconductor integrated circuit including an input terminal and an input circuit connected to the input terminal includes the following elements. A testing circuit is provided between the input terminal and the input circuit, and changes a resistance value between the input terminal and a predetermined potential. A test terminal is adapted to operate the testing circuit.

### CROSS REFERENCES TO RELATED APPLICATIONS

The present invention contains subject matter related to Japanese Patent Application JP 2005-116209 filed in the Japanese Patent Office on Apr. 13, 2005, the entire contents of which are incorporated herein by reference.

### BACKGROUND OF THE INVENTION

1. Field of the Invention

The present invention relates to semiconductor integrated circuits. More specifically, the present invention relates to a semiconductor integrated circuit using bump technology and a method for testing a connection state between semiconductor integrated circuits.

2. Description of the Related Art

With the recent demands for high-performance high-speed electronic devices, such as personal computers (PCs), home game devices, and portable terminals, demands for higher density and more layers in semiconductor integrated circuits used for the electronic devices have increased.

One of the mainstream methods for increasing the density of semiconductor integrated circuits has been to form a one-chip device, or to form all systems on a single chip (a system-on-a-chip method). However, multiple functions on one chip lead to problems of low yield due to the failure of the individual functions, complexity of process steps, longer TATs, high development cost, and so forth.

In order to overcome such problems, the so-called System-in-Package (SiP) solutions for assembling a plurality of semiconductor chips into a single package have increasingly attracted attention. The SiP solutions include Multi-Chip-Module/Multi-Chip-Package (MCM/MCP) technology and Chip-on-Chip packaging technology.

Side-by-side packages and chip-stack packages are mainstream packages. The side-by-side packages are fabricated by placing a plurality of semiconductor chips side-by-side on the same substrate, and the chip-stack packages are fabricated by stacking a plurality of semiconductor chips in multiple layers and wire-bonding the chips to a substrate.

Particularly, the wire-bonded chip-stack packages fabricated by stacking semiconductor chips provide high density.

However, in a case where thousands of connections between semiconductor chips are needed, the wire-bonded chip-stack packages are costly and the package size becomes large.

Therefore, packaging technology in which a plurality of semiconductor chips are stacked in multiple layers and the semiconductor chips are connected using bumps has increasingly attracted attention (a package fabricated by this packaging technology is hereinafter referred to as a “bump package”). This is chip-on-chip packaging technology using bumps.

In a case where hundreds or thousands of connections between semiconductor chips are needed, the bump packages do not need the space for wire bonding, and are less costly than the chip-stack packages.

However, the connection quality of the bump packages is lower than that of the wire-bonded packages. Thus, a technique for improving the connection quality and establishment of an inspection test for the connection quality in the manufacturing process may be needed.

Some inspection tests for the connection quality are performed by visual inspection or by using test pads. In the bump-packaged semiconductor integrated circuits, most of the connections are established between only semiconductor chips, and most connections using bumps are not exposed to the outside so that it is difficult to provide test pads due to the limited space. Therefore, a method in which it is determined whether or not a signal can be transmitted and received between semiconductor chips to test the connection of the semiconductor chips is used. Specifically, an output signal from a first semiconductor chip is input to a second semiconductor chip, and it is determined whether or not the second semiconductor chip can receive the output signal to check the connection of both chips (see, for example, Japanese Examined Patent Application Publication No. 3-51306 and Japanese Unexamined Patent Application Publication No. 2-99877).

In recent semiconductor integrated circuits, generally, JTAG (which is a standard proposed by the Joint Test Action Group and adopted as IEEE std 1149.1-1990 “Standard Test Access Port and Boundary-Scan Architecture”) components are mounted on semiconductor chips. This makes it easy to output a signal from a first semiconductor chip and to receive the signal at a second semiconductor chip, and allows the connection test described above with ease.

### SUMMARY OF THE INVENTION

In the connection testing methods disclosed in the publications mentioned above, although it is possible to determine whether or not semiconductor chips are connected, it is difficult to test the extent to which the semiconductor chips are connected.

Meanwhile, with the recent high-density packaging in semiconductor integrated circuits, the size of bumps used in the bump packages has been reduced year-by-year. In the manufacturing process, the bumps can be connected with a deviation from the normal positions, leading to unreliable contact to some extent.

If such unreliable-contact semiconductor devices are assembled into electronic equipment and are sold as products in the market, connection failure at the bumps can occur depending on the use environment. Particularly, in an environment where the products are used in places with a large difference in temperature and/or humidity, connection failure is more likely to occur.

Therefore, elimination of unreliable-contact devices by testing the connection state of bumps improves the package quality.

One method for testing the connection state of bumps is to output a signal from a first semiconductor chip and to measure a current value when a second semiconductor chip receives the signal to measure a connection resistance value.

The method in which a current value is measured to measure a connection resistance value will be described in detail with reference to FIG. 4. FIG. 4 is a diagram of a System-in-Package semiconductor integrated circuit (hereinafter referred to as a “SiP semiconductor integrated circuit”) 200, showing a method in which a current value is measured to test the connection state between semiconductor chips.

As shown in FIG. 4, the SiP semiconductor integrated circuit 200 includes a first semiconductor chip 201 and a second semiconductor chip 202, and the semiconductor chips 201 and 202 are connected using a bump 203. The bump 203 is a so-called internal bump, which provides a connection only between the semiconductor chips 201 and 202 and is not connected to any component.

The first semiconductor chip 201 includes two transistors 210 and 211 for selecting the signal to be output to the second semiconductor chip 202 from a signal from an internal circuit 212 and a signal from an input terminal 204.

The second semiconductor chip 202 includes two transistors 220 and 221 for selecting the signal to be output to an output terminal 205 from the signal from the first semiconductor chip 201 and a signal from an internal circuit 222.

In the semiconductor integrated circuit 200 having the structure described above, in order to test the connection state between the semiconductor chips 201 and 202, first, the transistors 211 and 220 are turned on and the transistors 210 and 221 are turned off, thereby connecting the input terminal 204 and the output terminal 205 via the transistors 211 and 220 and the bump 203.

Then, an LSI tester 230 applies a voltage between the input terminal 204 and the output terminal 205, and measures a current flowing therebetween to measure a resistance value Rtotal between the input terminal 204 and the output terminal 205.

The resistance value Rtotal is the sum of on-resistances Ra and Rb of the transistors 211 and 220 and a bump-connection resistance R_{B}, as given by the following equation:
Rtotal=Ra+Rb+R_{B} Eq. (1)

Thus, once the on-resistances Ra and Rb of the transistors 211 and 220 are determined, the resistance value R_{B} of the bump 203 is determined by subtracting the on-resistance values Ra and Rb of the transistors 211 and 220 from the resistance value Rtotal measured by the LSI tester 230.

However, transistors may often have an on-resistance of several hundreds of ohms, and the bump resistance is generally 1 Ω or less. Thus, it is difficult to accurately measure a bump resistance by using the calculation described above. Further, the on-resistance of transistors has variations of about 20% due to the variations in production, etc., and it is therefore difficult to measure the on-resistance.

Further, in the testing method, it may be necessary to measure bump resistances one by one, which may thus require a long test time.

Further, two transistors may be needed for a single input and output circuit. Thus, if a large number of bumps for connecting between semiconductor chips exist, the space for fabricating the transistors on the semiconductor chips and the wiring space for assembling the transistors are large, which is costly.

It is therefore desirable to provide a semiconductor integrated circuit and a method for testing a connection state between semiconductor integrated circuits in which the connection state of the semiconductor integrated circuits connected through bumps can accurately be tested.

According to an embodiment of the present invention, a semiconductor integrated circuit including an input terminal and an input circuit connected to the input terminal includes the following elements. A testing circuit is provided between the input terminal and the input circuit, and changes a resistance value between the input terminal and a predetermined potential. A test terminal is adapted to operate the testing circuit. It is therefore possible to accurately detect contact failure of bumps used for connection between semiconductor chips.

According to another embodiment of the present invention, a semiconductor integrated circuit including a plurality of input terminals and a plurality of input circuits correspondingly connected to the plurality of input terminals includes the following elements. A plurality of testing circuits are provided between the input terminals and the input circuits, and change resistance values between the input terminals and a predetermined potential. A common test terminal is adapted to operate the plurality of testing circuits. It is therefore possible to accurately detect contact failure of bumps used for connection between semiconductor chips. Further, a single test terminal provided for a semiconductor chip is sufficient for testing, thus preventing an increase in the number of wiring lines from the semiconductor chip.

The testing circuit may change the resistance value between the input terminal and the predetermined potential according to a voltage applied to the test terminal. It is therefore possible to accurately detect contact failure of bumps used for connection between semiconductor chips merely by changing the voltage applied to the test terminal.

A portion of a protection circuit used for the input circuit may be formed of the testing circuit. Therefore, a portion of the protection circuit can also be used as a testing circuit, thus preventing a further increase in the number of circuits.

According to another embodiment of the present invention, a method for testing a connection state between an output terminal of a first semiconductor integrated circuit and an input terminal of a second semiconductor integrated circuit includes the steps of controlling the first semiconductor integrated circuit to output a voltage of a predetermined level from the output terminal; controlling a testing circuit that is provided in the second semiconductor integrated circuit and that changes a resistance value between the input terminal and a predetermined potential to change a voltage of the input terminal; comparing the voltage of the input terminal and a predetermined threshold in the second semiconductor integrated circuit; and testing the connection state according to a result of the step of comparing. It is therefore possible to accurately detect contact failure of bumps used for connection between semiconductor chips. Further, a single test terminal provided for a semiconductor chip is sufficient for testing, thus preventing an increase in the number of wiring lines from the semiconductor chip.

The testing circuit may be controlled by applying a predetermined voltage to a test terminal that is provided for the second semiconductor integrated circuit and that is adapted to operate the testing circuit, and the method may further include the step of resetting the predetermined voltage according to a result of the step of comparing. It is therefore possible to set the test terminal depending on the characteristics of the semiconductor integrated circuits. Thus, there is no need to set a threshold in advance.

### BRIEF DESCRIPTION OF THE DRAWINGS

FIG. 1 is a diagram showing the external appearance of a semiconductor device according to an embodiment of the present invention;

FIG. 2 is a diagram showing the principle for testing a bump-connection state in a semiconductor device according to an embodiment of the present invention;

FIG. 3 is a diagram showing an operation of testing a bump-connection state in a semiconductor device according to an embodiment of the present invention; and

FIG. 4 is a diagram of a SiP semiconductor integrated circuit, showing a method in which a current value is measured to test a connection state between semiconductor chips.

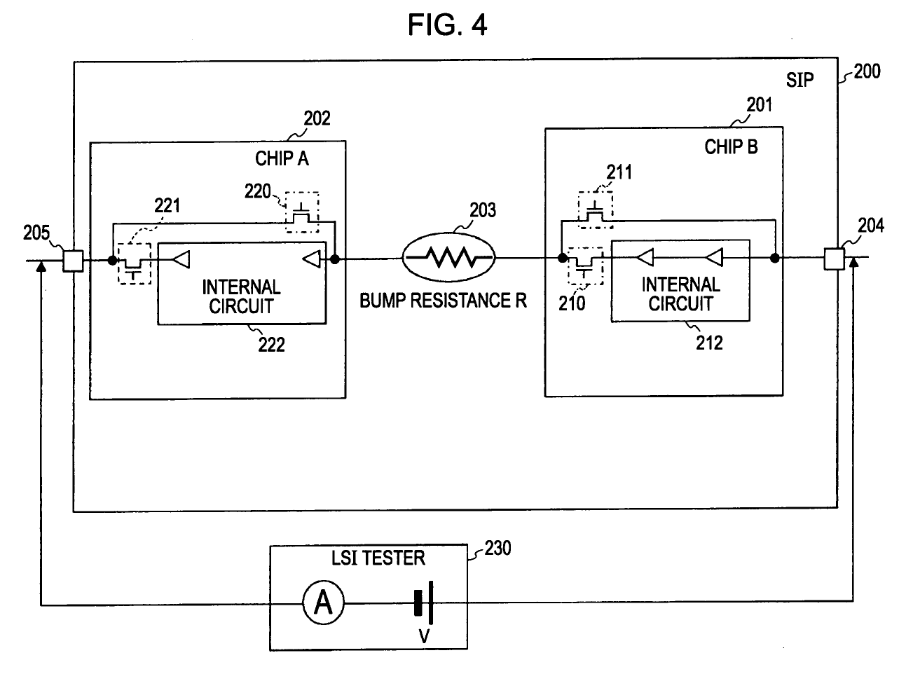

### DESCRIPTION OF THE PREFERRED EMBODIMENTS

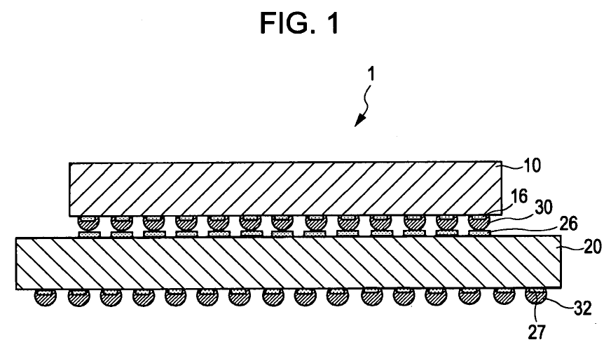

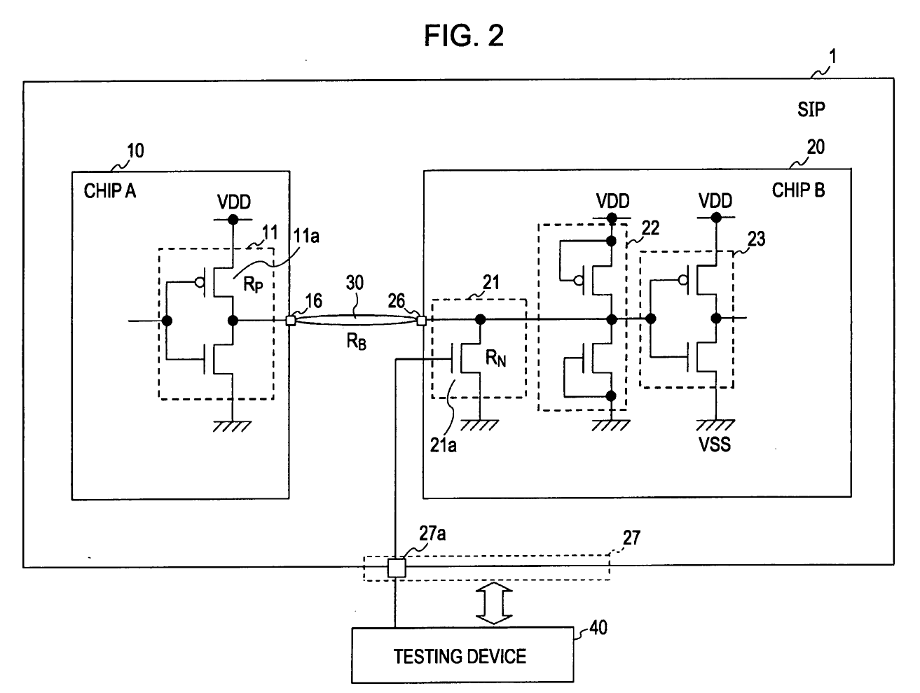

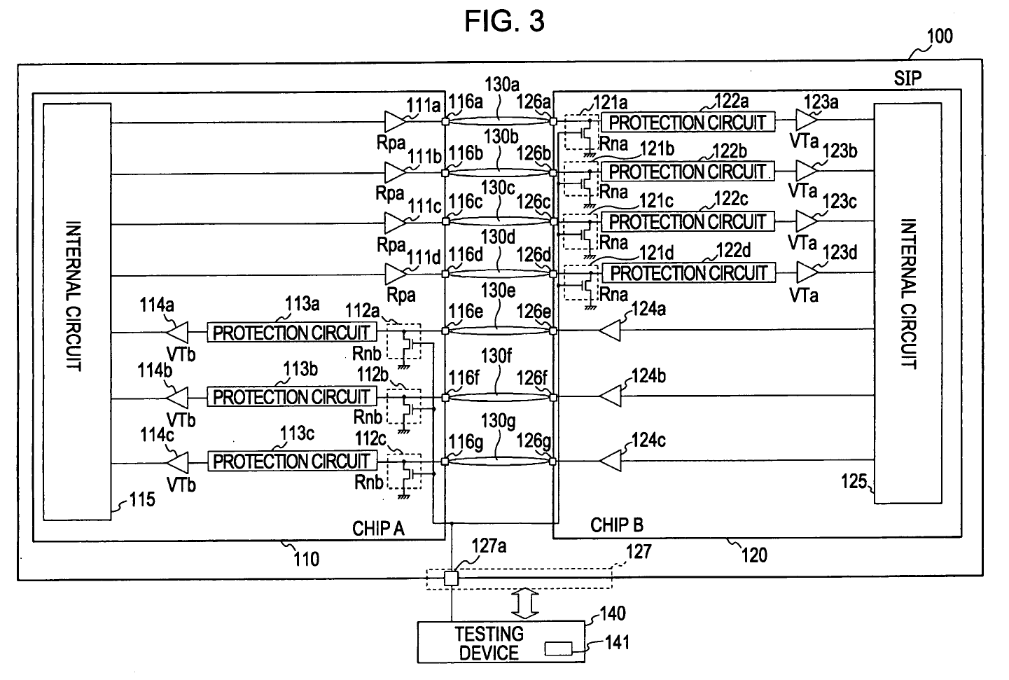

An embodiment of the present invention will be described hereinbelow. FIG. 1 is a diagram showing the external appearance of a semiconductor device according to an embodiment of the present invention. FIG. 2 is a diagram showing the principle for testing a bump-connection state in the semiconductor device according to an embodiment of the present invention. FIG. 3 is a diagram showing an operation of testing a bump-connection state in a semiconductor device according to an embodiment of the present invention.

As shown in FIG. 1, a semiconductor device 1 according to an embodiment of the present invention includes a first semiconductor chip 10 (a first semiconductor integrated circuit according to an embodiment of the present invention), and a second semiconductor chip 20 (a semiconductor integrated circuit or a second semiconductor integrated circuit according to an embodiment of the present invention). The semiconductor device 1 has a chip-on-chip SiP structure in which electrodes 16 disposed on the first semiconductor chip 10 and electrodes 26 disposed on the second semiconductor 20 are connected through bumps 30.

The second semiconductor chip 20 is provided with a plurality of electrodes 27 on the surface opposite to the surface on which the electrodes 26 are disposed for connecting the semiconductor device 1 to a substrate of an electric apparatus or the like, and the electrodes 27 are provided with bumps 32. The term “bump” as used herein means either a plurality of bumps or a single bump. In FIG. 1, each of reference numerals 16, 26, and 27 denotes one electrode, and each of reference numerals 30 and 32 denotes one bump. However, as shown in FIG. 1, a plurality of electrodes and bumps are provided.

With regard to the semiconductor device 1 in which the two semiconductor chips 10 and 20 are connected through the plurality of bumps 30, an arrangement for testing the connection state of the bumps 30 will specifically be described with reference to FIG. 2.

As shown in FIG. 2, in the semiconductor device 1 according to the embodiment, the first semiconductor chip 10 is provided with an output buffer 11, and the second semiconductor chip 20 provided with an input buffer 23. The output buffer 11 is connected to the input buffer 23 via the electrode 16 of the first semiconductor chip 10, the bump 30, and the electrode 26 of the second semiconductor chip 20, and a signal from the first semiconductor chip 10 is input to the second semiconductor chip 20 via the electrode 16, the bump 30, and the electrode 26 for processing. The electrode 16 connected to the output buffer 11 is hereinafter referred to as an “output terminal”, and the electrode 26 connected to the input buffer 23 is hereinafter referred to as an “input terminal”.

In the upstream of the input buffer 23 of the second semiconductor chip 20, that is, between the input terminal 26 and the input buffer 23, a testing circuit 21 according to an embodiment of the present invention and a protection circuit 22 for protecting the input buffer 23 against electrostatic discharge, surge, etc., are provided. For example, the protection circuit 22 can be formed of a MOS transistor or a diode using a junction.

An electrode 27a, which is one of the electrodes 27 of the second semiconductor chip 20, is used for operating the testing circuit 21. The electrode 27a is hereinafter referred to as a “test terminal”.

As shown in FIG. 2, the output buffer 11 is composed of a p-channel transistor 11a and an n-channel transistor. The testing circuit 21 is composed of an n-channel transistor 21a. The protection circuit 22 is composed of a p-channel transistor and an n-channel transistor. The input buffer 23 is composed of a p-channel transistor and an n-channel transistor.

In the semiconductor device 1 having the structure described above, a testing device 40 for testing the connection state of the bump 30 is connected to the electrodes 27 of the second semiconductor chip 20 via the bump 32. The testing device 40 controls the semiconductor device 1 to test the connection state of the bump 30. The testing method by the testing device 40 will specifically be described.

First, the testing device 40 controls the first semiconductor chip 10 and the second semiconductor chip 20 via a predetermined bump 32 and electrode 27 of the second semiconductor chip 20 to output a high-level (Vdd) signal from the output buffer 11 of the first semiconductor chip 10 and to output an input result in the input buffer 23 of the second semiconductor chip 20 to the testing device 40.

Then, the testing device 40 applies a predetermined voltage V1 to the bump corresponding to the test terminal 27a provided for the second semiconductor chip 20, and causes the transistor 21a of the testing circuit 21 to operate in an unsaturated operation state. Then, while changing the applied voltage V1, the testing device 40 detects a threshold voltage Vt for detecting a high-level voltage in the input buffer 23, and a voltage V1t applied at this time.

If the on-resistance of the transistor 11a of the output buffer 11 is denoted by R_{P}, the connection resistance of the bump 30 is denoted by R_{B}, and the on-resistance of the transistor 21a for the applied voltage V1t is denoted by R_{N}, the following equation is satisfied:
Vt/Vdd=R_{N}/(R_{P}+R_{B}+R_{N}) Eq. (2)

Thus, for example, when Vt=1.5 V, Vdd=3 V, R_{P}=500 Ω, and the connection resistance R_{B} of the bump 30 has a normal range of 0 to 5 Ω, the on-resistance R_{N} has the following range:
500 (Ω)≦R_{N}≦505 (Ω)
The testing device 40 applies a voltage to the transistor 21a so that the on-resistance R_{N} has a value in the range described above, thereby accurately testing the bump-connection state.

The values Vt, Vdd, and R_{P} depend on the transistor sizes of the input and output buffers 11 and 23 in the semiconductor chips 10 and 20 and the wafer process. The value R_{N} also depends on the transistor sizes of the protection circuit 22 and the wafer process in addition to the voltage V1 applied to the protection circuit 22.

In the manufacturing process of semiconductor chips, the characteristics of these resistances may have variations of about ±20%. In such a case, a problem may occur if the bump connection resistance R_{B} is measured simply by Eq. (2).

On the other hand, transistors of the same type (e.g., p-channel transistors) incorporated in the same semiconductor chip have the same manufacturing conditions if the transistor sizes are the same, and the characteristics of these transistors have small variations and are close to each other.

Thus, in the semiconductor device 1, in a case where the semiconductor chips 10 and 20 include a plurality of input buffers and output buffers, the buffer characteristics of the input buffers or the output buffers are substantially the same as long as the transistor configurations, sizes, and types are the same. In a case where the semiconductor chips 10 and 20 include a plurality of protection circuits, the characteristics of the protection circuits are also substantially the same as long as the transistor configurations, sizes, and types are the same.

A semiconductor device 100 and a testing device 140 capable of testing the connection state of a bump by using this feature described above and Eq. (2) will specifically be described with reference to FIG. 3.

Like the semiconductor device 1, the semiconductor device 100 is also a chip-on-chip SiP semiconductor device in which a first semiconductor chip 110 (a first semiconductor integrated circuit according to an embodiment of the present invention) and a second semiconductor chip 120 (a semiconductor integrated circuit or a second semiconductor integrated circuit according to an embodiment of the present invention) are connected through internal bumps 130. The external appearance of the semiconductor device 100 is similar to that of the semiconductor device 1 shown in FIG. 1, and the respective components are given reference numerals obtained by adding 100 to the reference numerals of the corresponding components shown in FIG. 1.

The first semiconductor chip 110 includes output buffers 111a to 111d for outputting data from an internal circuit 115, electrodes 116a to 116d connected to the output buffers 111a to 111d, respectively, electrodes 116e to 116g, testing circuits 112a to 112c connected to the electrodes 116e to 116g, respectively, protection circuits 113a to 113c connected to the testing circuits 112a to 112c, respectively, and input buffers 114a to 114c connected to the protection circuits 113a to 113c, respectively, for outputting the signals input to the electrodes 116e to 116g to the internal circuits 115.

The second semiconductor chip 120 includes electrodes 126a to 126d, testing circuits 121a to 121d connected to the electrodes 126a to 126d, respectively, protection circuits 122a to 122d connected to the testing circuits 121a to 121d, respectively, input buffers 123a to 123d connected to the protection circuits 122a to 122d, respectively, for outputting the signals input to the electrodes 126a to 126d to an internal circuit 125, output buffers 124a to 124c for outputting the data from the internal circuit 125, and electrodes 126e to 126g connected to the output buffers 124a to 124c, respectively.

The second semiconductor chip 120 further includes a plurality of electrodes 127 on the surface opposite to the surface on which the electrodes 126 are disposed, and an electrode 127a, which is one of the electrodes 127, is used for operating the testing circuits 112a to 112c and 121a to 121d. The electrode 127a is hereinafter referred to as a “test terminal”. The electrodes 116e to 116g connected to the input buffers 114a to 114c, respectively, and the electrodes 126a to 126d connected to the input buffers 123a to 123d, respectively, are hereinafter referred to as “input terminals”. The electrodes 116a to 116d connected to the output buffers 111a to 111d, respectively, and the electrodes 126e to 126g connected to the output buffers 124a to 124c, respectively, are hereinafter referred to as “output terminals”.

The output buffers 111a to 111d provided for the first semiconductor chip 110 are connected to the input buffers 123a to 123d provided for the second semiconductor chip 120 via the electrodes 116a to 116d, the bumps 130a to 130d, and the electrodes 126a to 126d, respectively. The signals from the first semiconductor chip 110 are input to the second semiconductor chip 120 for processing.

The output buffers 124a to 124c provided for the second semiconductor chip 120 are connected to the input buffers 114a to 114c provided for the first semiconductor chip 110 via the electrodes 126e to 126g, the bumps 130e to 130g, and the electrodes 116e to 116g, respectively. The signals from the second semiconductor chip 120 are input to the first semiconductor chip 110 for processing.

In the upstream of the input buffers 114a to 114c of the first semiconductor chip 110, that is, between the input buffers 114a to 114c and the electrodes 116e to 116g, the testing circuits 112a to 112c and the protection circuits 113a to 113c adapted to protect the input buffers 114a to 114c against electrostatic discharge, surge, etc., are provided, respectively. In the upstream of the input buffers 123a to 123d of the second semiconductor chip 120, that is, between the input buffers 123a to 123d and the electrodes 126a to 126d, the testing circuits 121a to 121d and the protection circuits 122a to 122d adapted to protect the input buffers 123a to 123d against electrostatic discharge, surge, etc., are provided, respectively.

The output buffers 111a to 111d and 124a to 124c correspond to and have the same configuration as the output buffer 11 described above. The input buffers 114a to 114c and 123a to 123d correspond to and have the same configuration as the input buffer 23 described above. The protection circuits 113a to 113c and 122a to 122d correspond to and have the same configuration as the protection circuit 22 described above. The testing circuits 112a to 112c and 121a to 121d correspond to and have the same configuration as the testing circuit 21 described above. However, the transistor sizes of the output buffers 111a to 111d and 124a to 124c, the input buffers 114a to 114c and 123a to 123d, the protection circuits 113a to 113c and 122a to 122d, and the testing circuits 112a to 112c and 121a to 121d differ from the transistor sizes of the corresponding buffers and circuits shown in FIG. 2.

The on-resistances of the output buffers 111a to 111d are the same, e.g., R_{P}a, and the on-resistances of the output buffers 124a to 124c are the same, e.g., R_{P}b. The threshold voltages of the input buffers 123a to 123d are the same, e.g., Vta, and the threshold voltages of the input buffers 114a to 114c are the same, e.g., Vtb. The characteristics of the unsaturated regions of the testing circuits 121a to 121d are the same, and the characteristics of the unsaturated regions of the testing circuits 112a to 112c are also the same.

In the semiconductor device 100 having the structure described above, a testing device 140 for testing the connection state of the bumps 130 is connected to the electrodes 127 of the second semiconductor chip 120 via the bumps 132. The testing device 140 controls the semiconductor device 100 to test the connection state of the bumps 130. The testing method by the testing device 140 will specifically be described.

First, the testing device 140 controls the first semiconductor chip 110 and the second semiconductor chip 120 via a predetermined bump 132 of the second semiconductor chip 120 to output a high-level (Vdd) signal from the output buffer 111a of the first semiconductor chip 110 and to output an input result in the input buffer 123a of the second semiconductor chip 120 to the testing device 140.

Then, the testing device 140 applies a predetermined voltage V2 to the bump corresponding to the test terminal 127a provided for the second semiconductor chip 120, and causes the transistor of the testing circuit 121a to operate in an unsaturated operation state. Then, while changing the applied voltage V2, the testing device 140 detects a threshold voltage Vta (Vin) for detecting a high-level voltage in the input buffer 123a, and a voltage V2t applied at this time.

The testing device 140 stores the voltage V2t in a storage unit 141.

If the on-resistance of the transistor of the output buffer 111a is denoted by R_{P}, the connection resistance of the bump 130 is denoted by R_{B}, the on-resistance of the transistor 121a for the applied voltage V2t is denoted by R_{N}, and a voltage Vin is input to the input buffer 123a for the applied voltage V2t, the following equation is satisfied:
Vin/Vdd=R_{N}/(R_{P}+R_{B}+R_{N}) Eq. (3)

When the connection state of the bump 130 is normal, the connection resistance R_{B} of the bump 130 is several ohms or less, and the resistances R_{P} and R_{N} have values that are larger than that of the resistance R_{B} by two to three orders of magnitude. Thus, when the connection state of the bump 130 is normal, the connection resistance R_{B} of the bump 130 is sufficiently small to be negligible.

When the connection state of the bump 130 is not normal or abnormal, on the other hand, the connection resistance R_{B} is larger than the value when the connection state is normal by one to two orders of magnitude.

Consequently, the following equations are satisfied:

R_{B} in the normal connection state:
Vin/Vdd≈K/(1+K) Eq. (4)

R_{B} in the abnormal connection state:
Vin/Vdd=K/(1+M+K) Eq. (5)
where K=R_{N}/R_{P} and M=R_{B}/R_{P}.

Therefore, when the connection state of the bump 130 is not normal or abnormal, the value K is small. This means that the input buffer outputs a high voltage even when the voltage applied to the transistor of the testing circuit is low.

For example, when Vin=1.5 V, Vdd=3 V, R_{P}=500 Ω, and the connection resistance R_{B} of the bump 130 has a normal range of 0 to 5 Ω, the resistance R_{N} has a range of 500 (Ω)≦R_{N}≦505 (Ω)

When the connection resistance R_{B} of the bump 130 has an abnormal range of 50 Ω or higher, the resistance R_{N} in the abnormal connection state has a range of 550 (Ω)≦R_{N}.

The value of the resistance R_{N} becomes small when the applied voltage V2 to the testing circuit increases, and becomes large when the applied voltage V2 decreases. Thus, the applied voltage V2 to the testing circuit may be a voltage V2t′ lower than the voltage V2t stored in the storage unit 141. The testing operation of the testing device 140 is performed accordingly.

Specifically, the testing device 140 applies a voltage V2t′ a predetermined voltage V3 lower than the voltage V2t stored in the storage unit 141 to the test terminal 127a. The voltage V3 is a predetermined voltage depending on the characteristics of the output buffer and the input buffer for determining abnormality of the connection state of the bumps 130, and is stored in the storage unit 141.

Then, the first semiconductor chip 110 and the second semiconductor chip 120 are controlled via a predetermined bump 132 of the second semiconductor chip 120 to simultaneously output high-level (Vdd) signals from the output buffers 111b to 111d of the first semiconductor chip 110 and to output input results in the input buffers 123b to 123d of the second semiconductor chip 120 to the testing device 140.

When any of the input results in the input buffers 123b to 123d is at the high level, it is determined that the connection state of the bump 130 corresponding to the input buffer that inputs the high-level signal is not normal.

In the testing device 140, when the connection state of the bumps 130 is tested, one of the input buffers having equivalent characteristics is selected, and a voltage is applied to the input of the testing circuit so that the voltage is set to the voltage obtained by adding a predetermined value to the threshold voltage Vta of the selected input buffer. Alternatively, a plurality of input buffers may be selected, and a voltage V2t for allowing all of the selected input buffers to detect high-level signals may be determined while changing the voltage applied to the test terminal 127a. Also in this case, based on the voltage V2t, abnormality of the connection state of the bump corresponding to the set of the input buffer and output buffer having the same characteristics is detected.

Likewise, subsequently, the testing device 140 examines the sets of the input buffers and output buffers having the same characteristics to sequentially test the connection states of the bumps corresponding to the input buffers and the output buffers, whereby abnormality of the connection state of a plurality of bumps in the semiconductor device 100 can accurately be detected.

As discussed above, in the semiconductor device 100 and the testing device 140 according to this embodiment, a plurality of testing circuits are provided between a plurality of input terminals and a plurality of input buffers of a semiconductor chip incorporated in the semiconductor device 100, and the testing circuits are operated by a common test terminal. The testing device 140 applies a voltage to the test terminal to operate the testing circuits, and a reference voltage is determined based on output results of some of the input buffers and is stored. The testing device 140 further applies the reference voltage to the test terminal, and determines abnormality of the connection state of the bumps from the output results of the remaining input buffers.

The determination of the reference voltage and the determination based on the reference voltage are performed only for a set of an input buffer and output buffer having the same characteristics. When a plurality of sets exist, the determination of the reference voltage and the determination based on the reference voltage are performed for each of the sets.

According to the semiconductor device and the testing device of this embodiment, therefore, a plurality of testing circuits are provided between a plurality of input terminals and a plurality of input buffers of a semiconductor chip incorporated in the semiconductor device, and these testing circuits are operated by a single test terminal. It is therefore possible to accurately detect contact failure of bumps used for connection between semiconductor chips.

Further, a common test terminal provided for a semiconductor chip is sufficient for testing, thus preventing an increase in the number of wiring lines from the semiconductor chip.

Furthermore, it is possible to simultaneously test the connection of bumps corresponding to sets of input buffers and output buffers having the same characteristics, thus greatly reducing the testing time as compared to testing of individual connections of bumps.

If several hundreds of bumps are simultaneously tested, a current of several amperes or more may be needed, resulting in a potential difference in the power supply line to cause a reduction in test accuracy. The number of high-level signals to be output at the same time from the output buffers is limited, thereby avoiding this problem.

While, in the embodiments described above, in order to test a bump connection state, a testing circuit is provided between an input terminal and a ground potential, and the testing circuit is operated to change the resistance value between the input terminal and the ground potential, the converse configuration may be employed. That is, a p-channel transistor may be used as a testing circuit. This testing circuit may be provided between an input terminal and a Vdd potential, and the testing circuit may be operated to change the resistance value between the input terminal and the Vdd potential. A low-level signal may be output from an output buffer, thereby testing the connection state of a bump.

Alternatively, one transistor in a protection circuit may be used as a testing circuit. For example, in a case where the testing is performed by outputting a high-level signal from an output buffer, the n-channel transistor in the protection circuit is also used as a testing circuit. In a case where the testing is performed by outputting a low-level signal from an output buffer, the p-channel transistor in the protection circuit is also used as a testing circuit. This prevents a further increase in the number of circuits.

It should be understood by those skilled in the art that various modifications, combinations, sub-combinations and alterations may occur depending on design requirements and other factors insofar as they are within the scope of the appended claims or the equivalents thereof.

1. A semiconductor integrated circuit including an input terminal and an input circuit connected to the input terminal, the semiconductor integrated circuit comprising:
a testing circuit that is provided between the input terminal and the input circuit and that changes a resistance value between the input terminal and a predetermined potential; and
a test terminal adapted to operate the testing circuit.

2. A semiconductor integrated circuit including a plurality of input terminals and a plurality of input circuits correspondingly connected to the plurality of input terminals, the semiconductor integrated circuit comprising:
a plurality of testing circuits that are provided between the input terminals and the input circuits and that change resistance values between the input terminals and a predetermined potential; and
a common test terminal adapted to operate the plurality of testing circuits.

3. The semiconductor integrated circuit according to claim 1, wherein the testing circuit changes the resistance value between the input terminal and the predetermined potential according to a voltage applied to the test terminal.

4. The semiconductor integrated circuit according to claim 1, wherein a portion of a protection circuit used for the input circuit is formed of the testing circuit.

5. A method for testing a connection state between an output terminal of a first semiconductor integrated circuit and an input terminal of a second semiconductor integrated circuit, the method comprising the steps of:
controlling the first semiconductor integrated circuit to output a voltage of a predetermined level from the output terminal;
controlling a testing circuit that is provided in the second semiconductor integrated circuit and that changes a resistance value between the input terminal and a predetermined potential to change a voltage of the input terminal;
comparing the voltage of the input terminal and a predetermined threshold in the second semiconductor integrated circuit; and
testing the connection state according to a result of the step of comparing.

6. The method according to claim 5, wherein the testing circuit is controlled by applying a predetermined voltage to a test terminal, the test terminal being provided for the second semiconductor integrated circuit to operate the testing circuit, and
the method further comprises the step of resetting the predetermined voltage according to a result of the step of comparing.

7. A system-in-package in which a first semiconductor integrated circuit and a second semiconductor integrated circuit are connected using a bump, the system-in-package comprising:
a plurality of input terminals;
input circuits correspondingly connected to the input terminals;
a plurality of testing circuits that are provided between the input terminals and the input circuits and that change resistance values between the input terminals and a predetermined potential; and
a common test terminal adapted to operate the plurality of testing circuits.

8. The semiconductor integrated circuit according to claim 2, wherein the testing circuit changes the resistance value between the input terminal and the predetermined potential according to a voltage applied to the test terminal.

9. The semiconductor integrated circuit according to claim 2, wherein a portion of a protection circuit used for the input circuit is formed of the testing circuit.
